(19) United States
(12) Patent Application Publication
(10) Pub. No.: US 2025/0386516 A1
(43) Pub. Date: Dec. 18, 2025

(54) MEMORY CIRCUIT BASED ON A PHASE-CHANGE MATERIAL

(71) Applicant: STMicroelectronics International N.V., Geneva (CH)

(72) Inventors: Valentin BACQUIE, Grenoble (FR); Simon JEANNOT, Grenoble (FR); Thomas CABOUT, Grenoble (FR); Christian BOCCACCIO, Bernin (FR); Jury SANDRINI, Grenoble (FR)

(73) Assignee: STMicroelectronics International N.V., Geneva (CH)

(21) Appl. No.: 19/231,817

(22) Filed: Jun. 9, 2025

(30) Foreign Application Priority Data
Jun. 18, 2024 (FR) 2406452

(51) Int. Cl. H10B 63/10; G11C 5/06; H10B 63/00; H10N 70/00; H10N 70/20

(52) U.S. Cl. CPC H10B 63/10; G11C 5/063; H10B 63/30; H10B 63/84; H10N 70/011; H10N 70/235; H10N 70/8413

(57) ABSTRACT

The present description concerns an electronic device comprising a memory circuit, the circuit comprising: a substrate inside and on top of which are arranged selection transistors; an interconnection stack; a plurality of memory elements arranged above the interconnection stack and organized in an array, forming rows and columns, each memory element comprising a stack of a resistive heating element, of a layer made of a phase-change material, and of a top electrode, the top electrode being common to the memory elements of a same line, wherein the memory elements of two successive bit lines are separated by a trench comprising, in a lower portion, a closed space filled with a gas or with vacuum, the trench being closed by an insulating layer extending over the upper surface of the memory elements and in an upper portion of the trench.

### CROSS-REFERENCE TO RELATED APPLICATION(S)

This application claims the priority benefit of French patent application number 2406452, filed on Jun. 18, 2024, entitled “Circuit mémoire à base d'un matériau à changement de phase” which is hereby incorporated by reference to the maximum extent allowable by law.

### BACKGROUND

### Technical Field

The present disclosure generally concerns the field of electronic devices and more particularly aims at the field of electronic chips comprising a memory circuit, based on a phase-change material, and their manufacturing methods.

### Description of the Related Art

A phase-change material is a material having the ability to change crystalline state under the effect of heat, and more particularly to switch between a crystalline state and an amorphous state, more highly resistive than the crystalline state. This phenomenon is used to define two memory states, for example 0 and 1, differentiated by the resistance measured through the phase-change material.

There exists a use for improvement of electronic chips comprising memory circuit based on a phase-change material.

### BRIEF SUMMARY

For this purpose, an embodiment provides an electronic device comprising a memory circuit, the memory circuit comprising:
a semiconductor substrate inside and on top of which are arranged selection transistors;
an interconnection stack, arranged on an upper surface of the semiconductor substrate; and
a plurality of memory elements arranged above the interconnection stack and organized in an array, forming rows and columns,
each memory element comprising a stack of a resistive heating element, of a layer made of a phase-change material, and of a top electrode, the top electrode being common to the memory elements of a same row so as to form bit lines,
wherein the memory elements of two successive bit lines are separated by a trench comprising, in a lower portion, a closed space filled with a gas or with vacuum, the trench being closed by an insulating layer extending over the upper surface of the memory elements and in an upper portion of the trench.

According to an embodiment, the closed space is filled with air.

According to an embodiment, the trench has a width smaller than 150 nm, for example smaller than 118 nm, for example smaller than 100 nm.

According to an embodiment, the insulating layer is made of silicon nitride.

According to an embodiment, the insulating layer has a thickness, on the upper surface of the top electrode, greater than 75 nm.

According to an embodiment, the memory elements of a same column are memory elements of a same word line, each selection transistor associated with the memory elements of a same word line being coupled to a conductive via running through the interconnection stack.

Another embodiment provides a method of manufacturing an electronic device comprising a memory circuit comprising a plurality of memory elements organized in an array, forming rows and columns, each memory element comprising a stack of a resistive heating element, of a layer made of a phase-change material, and of a top electrode, the top electrode being common to the memory elements of a same row so as to form bit lines, wherein the memory elements of two successive bit lines are separated by a trench, the method comprising the steps of:
a) forming of selection transistors inside and on top of a semiconductor substrate;
b) forming of an interconnection stack, arranged on an upper surface of the semiconductor substrate;
c) forming of the memory elements above the interconnection stack; and
d) forming of an insulating layer extending over the upper surface of the memory elements and in an upper portion of the trenches so as to close the trenches and create, in a lower portion of each trench, a closed space filled with a gas.

According to an embodiment, the forming of the memory elements comprises the steps of:
forming of the resistive heating elements;
deposition of the layer made of the phase-change material;
deposition of the top electrode; and
etching of the layer made of the phase-change material and of the top electrode.

According to an embodiment, the method comprises, after step c), a step of deposition of another insulating layer on the upper surface and the flanks of the memory elements.

According to an embodiment, the other insulating layer is formed by an atomic layer deposition method.

According to an embodiment, the insulating layer is formed, at step d), by a method of plasma-enhanced chemical vapor deposition.

According to an embodiment, the insulating layer is formed, at step d), by a physical vapor deposition method.

According to an embodiment, the method comprises, after step b), a step of forming of a plurality of openings running through the entire height of the interconnection stack and a step of filling of these openings with a metallic material so as to form conductive vias.

Another embodiment provides a method of use of an electronic device such as described hereabove, the method comprising the application of a current in the resistive heating element of one of the memory elements, which results in a change in crystalline phase of the layer made of the phase-change material of the memory element, allowing the storage of a data bit.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a perspective view, partial and simplified, of an example of an electronic device according to an embodiment; and

FIG. 2, FIG. 3, FIG. 4, FIG. 5A, and FIG. 5B are views, partial and simplified, illustrating steps of an example of a method of manufacturing the electronic device shown in FIG. 1.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10% or 10°, preferably of plus or minus 5% or 5°.

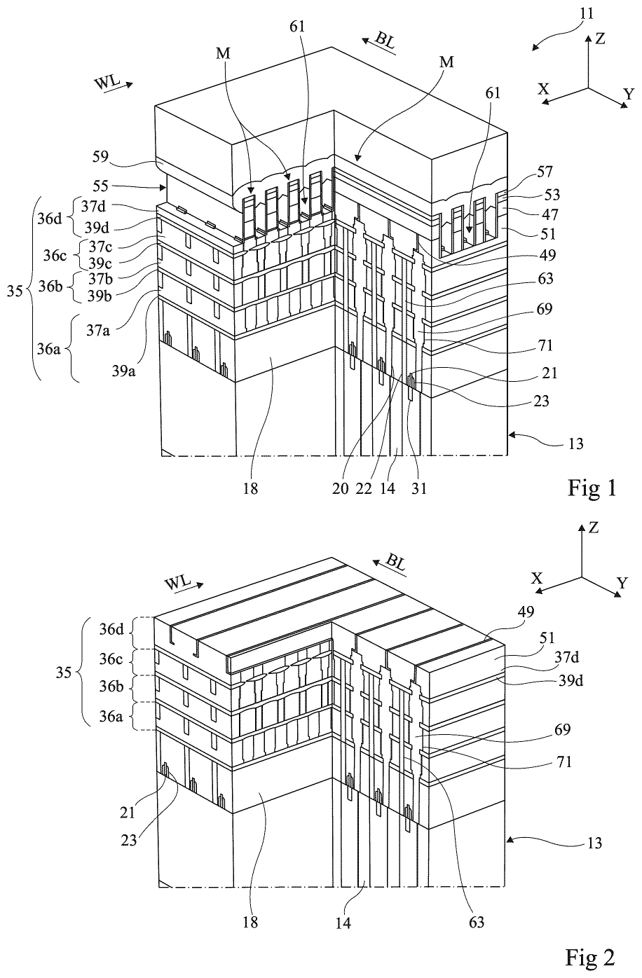

In the present disclosure, the embodiments of FIGS. 1 to 5B are shown in space according to a direct orthogonal XYZ reference frame, the Z axis of the reference frame being orthogonal to the upper surface of the electronic device.

FIG. 1 is a perspective view, partial and simplified, of an example of an electronic device according to an embodiment. More particularly, FIG. 1 is a perspective view in which a portion of the device has been removed to expose the inside of the device and more particularly to expose the inside of the device according to the cross-sections of the two orthogonal planes XZ and YZ.

Device 11 is for example an electronic chip.

Device 11 comprises a semiconductor substrate 13. As an example, substrate 13 is made of silicon or based on silicon.

Substrate 13 comprises, for example, a doped semiconductor layer, not shown, of a first conductivity type, for example type N, for example doped with arsenic or phosphorus atoms. The N-type doped layer for example rests on top of, and is for example in contact with, another doped semiconductor layer of substrate 13 of a second conductivity type, opposite to the first conductivity type, for example of type P, for example doped with boron atoms.

As an example, substrate 13 comprises another semiconductor layer, not shown, flush with its upper surface and resting, for example, on the N-type doped layer. The upper semiconductor layer is, for example, a layer formed by epitaxy from the upper surface of the N-type doped layer. The upper semiconductor layer is, for example, made of silicon, for example single-crystal silicon. The upper semiconductor layer comprises, for example, a plurality of regions of two opposite conductivity types, for example a plurality of P-type regions and a plurality of N-type regions, extending longitudinally in lines in a first direction. As an example, the regions of the upper semiconductor layer extend in the direction of the X axis. Substrate 13 thus comprises, at its upper surface, lines comprising an alternation of P-type regions and of N-type regions extending in the direction of the X axis.

As an example, the device comprises a plurality of transistors formed inside and on top of substrate 13. Each transistor comprises, for example, a single N-type region and a single P-type region.

As an example, the P-type and N-type regions of a same transistor are separated and are for example electrically insulated by an insulating trench 31. Insulating trenches 31 are, for example, super shallow trench isolation (SSTI) trenches. Trenches 31 extend longitudinally in the direction of the X axis.

Insulating trenches 31 extend, for example, from the upper surface of substrate 13, into substrate 13. Trenches 31 preferably extend in a portion of the upper semiconductor layer and in the N-type layer without reaching the P-type layer. Insulating trenches 31 are for example filled with a dielectric material, for example with silicon oxide. The depth of trenches 31 is, for example, in the range from 20 nm to 40 nm.

Each trench 31 is for example topped with a dummy gate pattern 21 arranged on the upper surface of substrate 13, for example extending longitudinally in the direction of the X axis. Gate patterns 21 extend, for example, along the entire length of trenches 31. Each gate pattern 21 is, for example, made of a semiconductor material, for example of polysilicon. As an example, the vertical flanks of each gate pattern 21 are covered by spacers 23. Spacers 23 are for example made of a dielectric material, for example of a nitride.

The transistors are for example separated from one another and are for example electrically insulated by insulating trenches 14. Insulating trenches 14 are, for example, shallow trench isolation (STI) trenches. Trenches 14 extend longitudinally in the direction of the X axis. As an example, trenches 14 are for example separated by an assembly formed by a trench 31 and a gate pattern 21.

Insulating trenches 14 extend, for example, from the upper surface of substrate 13 into substrate 13. Trenches 14 preferably extend in a portion of the upper semiconductor layer of substrate 13, in the N-type layer, and in a portion of the P-type layer. Insulating trenches 14 are for example filled with a dielectric material, for example with silicon oxide. As an example, trenches 14 are deeper than trenches 31. The depth of trenches 14 is, for example, in the range from 250 nm to 400 nm.

The transistors are for example arranged in an array comprising rows and columns.

Each transistor is comprised in an elementary memory cell. Each memory cell further comprises a memory element M, preferably formed at least partially opposite said transistor, for example opposite the P-type region of said transistor. N-type regions, unlike P-type regions, are for example not topped by memory elements M. As an example, within each memory cell, the transistor is a transistor for selecting memory element M.

Memory elements M are organized, in top view, in an array of rows and columns. It is respectively spoken of word lines, running in the direction of the Y axis, and of bit lines, running in the direction of the X axis. For example, each memory element M is located at the intersection of a bit line and of a word line. As an example, the memory elements M in the XZ plane are memory elements M of a same word line WL, while the memory elements in the YZ plane are memory elements of a same bit line BL.

Device 11 comprises, for example, an insulating layer 18 covering the upper surface of semiconductor substrate 13, and more precisely the upper surface of the semiconductor layer of substrate 13. Insulating layer 18 is, for example, in contact with the upper surface of the upper semiconductor layer of substrate 13. Insulating layer 18 covers, for example, the entire upper surface of the upper semiconductor layer of substrate 13. Insulating layer 18 for example has a thickness in the range from 80 nm to 300 nm, for example in the range from 120 nm to 200 nm.

Layer 18 is for example crossed by vias 20 and 22. Vias 20 and 22 are, for example, in contact, by their lower surfaces, with the upper surface of the semiconductor layer so that each N- and P-type region is topped with a via 20 or 22. Vias 20 and 22 extend, for example, along the entire height of layer 18. Vias 20 and 22 thus extend from the upper surface of layer 18 to the lower surface of layer 18. Vias 20 and 22 are for example made of a conductive material, for example of tungsten.

The device comprises an interconnection stack 35, for example covering layer 18. In this example, interconnection stack 35 is formed between substrate 13 and memory elements M. Interconnection stack 35 is for example formed on the upper surface of insulating layer 18 and for example covers the entire surface of insulating layer 18.

Interconnection stack 35 is for example formed of a succession of levels 36, each level 36 comprising an insulating layer 37 and an insulating layer 39. Interconnection stack 35 comprises, for example, a level 36a, comprising an insulating layer 39a formed on top of and in contact with the upper surface of insulating layer 18. Interconnection stack 35 further comprises, in level 36a, an insulating layer 37a formed on insulating layer 39a. For example, insulating layer 37a is formed over the entire surface of insulating layer 39a. As an example, insulating layer 37a is in contact, by its lower surface, with the upper surface of insulating layer 39a.

Interconnection stack 35 may further comprise additional levels formed on level 36a, that is, on top of and in contact with insulating layer 37a. In FIG. 1, interconnection stack 35 comprises three additional levels 36b, 36c, and 36d, for example respectively formed by layers 37b and 39b, layers 37c and 39c, and layers 37d and 39d. In practice, the number of levels in interconnection stack 35 may be different from four, for example greater than four.

As an example, interconnection stack 35 has a thickness in the range from 300 nm to 800 nm, for example in the range from 400 nm to 700 nm, for example in the order of 500 nm.

As an example, insulating layers 18 and 37 are made of a material having a low dielectric constant, for example made of a material having a dielectric constant (corresponding to the permittivity of said material relative to the permittivity of vacuum) lower than 5, for example lower than 4. Insulating layers 37 are for example made of silicon oxycarbide (SiOC), of porous silicon oxycarbide, of SiOCH, or of porous SiOCH. As an example, insulating layers 39 are made of a low permittivity oxide, known as “low k” or “ultra low k”.

Each level 36 comprises conductive vias 69 and conductive tracks 71, tracks 71 extending in layer 39 from, for example, the upper surface of layer 39, thus being flush with the upper surface of layer 39. Preferably, the tracks 71 of a level 36 extend exclusively in the layer 39 of said level 36. The vias 69 of a level of stack 35 extend through the layer 39 and through the layer 37 of the same level 36. More precisely, the vias 69 of a level of stack 35 extend from the lower surface of a track 71 of the same level to the lower surface of layer 37 or to the upper surface of a via 20 or 22 running through layer 18. As an example, heating element 49 rests on top of and is in contact, by its lower surface, with the upper surface of via 69 running through the layer 39 of the highest level 36 of stack 35.

Vias and conductive tracks 71 and 69 are for example made of a metallic material, for example of tungsten.

Alternatively, the opposing vias 69 and tracks 71 of the same memory cell M can be replaced by a single conductive via running through the entire thickness of the interconnection stack 35. By way of example, a single via passes through all the insulating layers 39 and 37 of the interconnection stack 35. In this variant, each single via is in contact, by its upper face, with the lower face of the heating element 49 of the memory cell M. Furthermore, in this variant, each single via is in contact, for example, by its lower face, with another conductive via 22, itself in contact with the upper face of the substrate 13. Furthermore, in this variant, the side walls of the single via are, for example, flat. The single vias do not comprise landings, for example. In this variant, the single vias have, for example, substantially constant lateral dimensions, for example a width, taken in the YZ and XZ planes of FIG. 1, of between 40 nm and 100 nm, for example of the order of 70 nm. In this variant, the single vias are produced, for example, by forming openings in the interconnection stack 35 opening onto the top face of the vias 22 and then depositing a layer of the material of the vias on the top face of the structure. During this stage, the material of the single vias completely fills the openings formed in the stack 35 in a single step. At the end of the single-via material deposition step, a polishing step can be performed to remove any excess material deposited on the upper surface of the structure. The single vias are made, for example, of a metallic material such as tungsten.

This variant makes it possible to overcome the constraints of metal level dimensioning for PCM cell integration, since the surface area of the single vias can be smaller than the surface area of a track on the surface of the interconnection stack 35.

This variant also advantageously reduces the electrical resistance from the substrate 13 to the heating element 49 by eliminating multiple interfaces between vias 69 and tracks 71.

As an example, each memory element M is electrically connected to the selection transistor with which it is associated via a conductive via 63 running through, for example, part only of the levels 36 of interconnection stack 35. As an example, via 63 runs through all the levels 36 of interconnection stack 35 except, for example, for the upper level of stack 35. In the embodiment of FIG. 1, vias 63 then run through levels 36a, 36b, and 36c, without running through level 36d of stack 35. Here, the vias then extend from the lower surface of layer 39a to the upper surface of layer 37c.

For example, the lower surface of via 63 is in contact with a conductive via 22, itself in contact with the upper surface of the P-type region of the transistor associated with memory element M.

Conductive via 63 is made of a metallic material, for example. Conductive via 63 is for example made of copper. As a variant, conductive via 63 is made of cobalt or of tungsten.

An advantage of forming memory elements M above stack 35 is that it enables to avoid risks of contamination of phase-change layer 47 generated by the forming of stack 35 and of the different metal levels 36.

An advantage of controlling word lines via vias 63 is that this enables to overcomes metal level sizing constraints for the integration of the phase-change elements, and thus to bring the word lines closer to memory elements M, since the width of vias 63 may be lower than the width of a conductive track.

Memory elements M are, in the embodiment of FIG. 1, formed on the upper surface of stack 35.

Memory elements M are phase-change memory elements. Each element comprises a layer 47 made of a phase-change material, for example a chalcogenide material, for example an alloy of germanium, antimony, and tellurium (GeSbTe) known as GST. Layer 47 has, for example, a thickness in the range from 30 nm to 100 nm, for example in the order of 50 nm. The memory elements M of a same bit line for example comprise a common layer 47. Thus, device 11 for example comprises as many layers 47 as there are bit lines. Each layer 47 thus extends in the bit line direction.

In each memory element M, the phase-change material is controlled by the metallic resistive heating element 49 located under the phase-change material. Element 49 is for example in contact, by its upper surface, with the lower surface of layer 47. Element 49 is for example laterally surrounded by a layer made of a thermal insulator 51. For example, each element 49 has an “L” shape in the YZ cross-section plane. As an example, element 49 is made of tantalum nitride or of titanium silicon nitride. As an example, layer 51 is made of silicon carbonitride. As an example, heating element 49 has, for example, a thickness in the range from 30 nm to 100 nm, for example in the order of 60 nm.

Layer 47 is topped with a layer 53, for example made of a conductive material, for example of a metallic material. More specifically, the upper surface of each layer 47 is for example at least partially covered, for example entirely covered, with a layer 53. Each layer 53 preferably extends, in the bit line direction, along the entire length of layer 47. Layer 53 is for example made of titanium nitride. As an example, layer 53 has a thickness in the range from 10 nm to 50 nm, for example in the order of 20 nm.

As an example, in each memory element M, metal element 49 and layer 53 respectively form a bottom and a top electrode of memory element, and more specifically electrodes of the variable-resistance resistive element formed by layer 47 made of the phase-change material. The memory elements M of a same bit line are topped with a same layer 53. In other words, the top electrodes 53 of the memory elements M of a same bit line are interconnected.

Layer 53 is, for example, topped with a layer 57, for example made of an insulating material, for example, of a dielectric material. Insulating layer 57 is for example made of a nitride, for example of silicon nitride. The upper surface of each layer 53 is for example at least partially covered, for example fully covered, with a layer 57. Each layer 57 preferably extends, in the bit line direction, along the entire length of the layer 53. As an example, layer 57 has a thickness in the range from 10 nm to 50 nm, for example in the order of 25 nm.

Each memory element M is for example covered with an insulating layer 55 protecting, for example, layer 47 made of the phase-change material from oxidation. As an example, layer 55 covers the upper surface of layer 57 and the flanks of layers 53, 57, 47, and 51. Layer 55 is for example made of a dielectric material. Insulating layer 55 is for example made of a nitride, for example of silicon nitride.

The memory elements M of neighboring bit lines are insulated from one another by a closed space 61 topped with an insulating layer 59. Closed space 61 is filled with a gas or with vacuum. As an example, closed space 61 is filled with air. As a variant, closed space 61 is filled with a neutral gas. Insulating layer 59 is, for example, made of a dielectric material, for example of a nitride, for example of silicon nitride. Layer 59 covers the upper surface of memory elements M and extends in an upper portion only of the depth of the trenches separating the bit lines of memory elements M. Closed space 61 is for example laterally delimited by layer 55 covering two neighboring memory elements M. Closed space 61 is further delimited by the upper surface of layer 37d or, where applicable, the layer 55 which covers layer 37d. Further, closed space 61 is delimited by the lower surface of layer 59. Each closed space 61 extends between two bit lines, for example along the entire length of the bit lines, for example in the direction of the Y axis.

To be able to apply potentials to the word lines of memory elements M, via 63 and vias 22 are for example longitudinally continued in the direction of the X axis outside the device illustrated in FIG. 1. To be able to apply potentials to the bit lines of memory elements M, the layer 53 corresponding to the top electrode is for example longitudinally continued in the direction of the Y axis outside the device illustrated in FIG. 1.

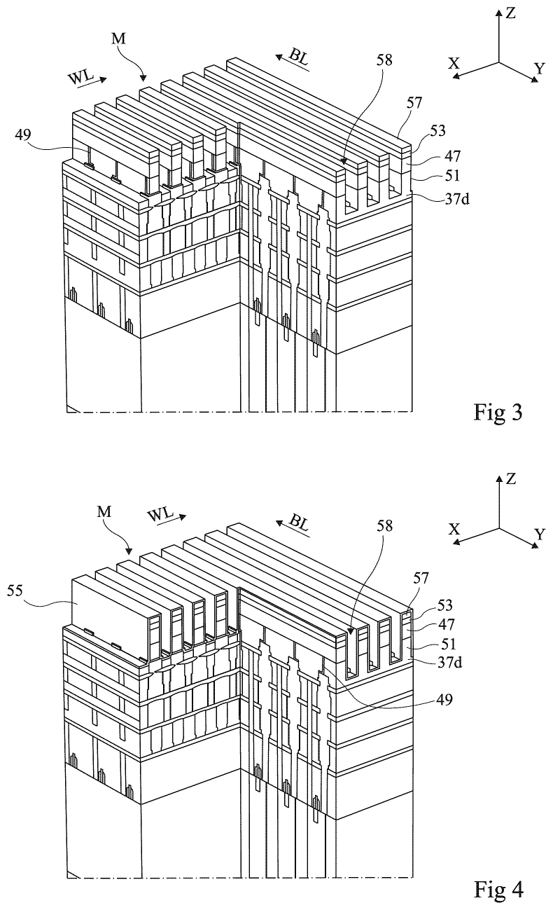

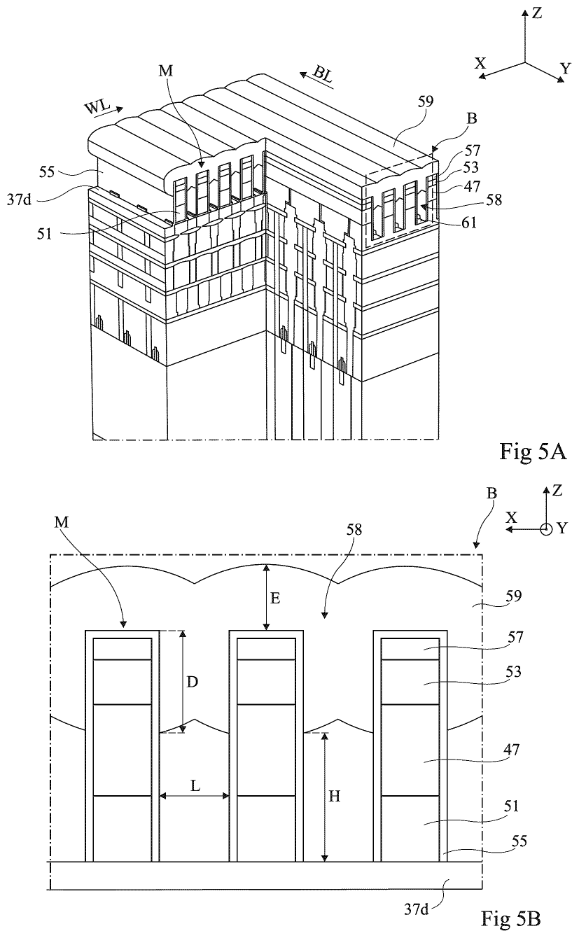

FIG. 2, FIG. 3, FIG. 4, FIG. 5A, and FIG. 5B are views, partial and simplified, illustrating steps of an example of a method of manufacturing the electronic device shown in FIG. 1.

FIG. 2 illustrates an initial structure and, more particularly, a perspective view of the initial structure.

As an example, the initial structure comprises the semiconductor substrate 13 on which interconnection stack 35 has been formed. The structure further comprises the layer 51 in which are formed resistive heating elements 49.

FIG. 3 illustrates a structure obtained at the end of a step of forming memory elements M on the upper surface of the structure shown in FIG. 2. More particularly, FIG. 3 shows a perspective view of the structure.

During this step, layers 47, 53, and 57 are for example successively deposited on the upper surface of the structure shown in FIG. 2. During this step, layers 47, 53, and 57 are deposited all over the wafer, for example, so as to cover the entire surface of layer 51.

At the end of the deposition of layers 47, 53, and 57 they are for example etched to form, in these layers, trenches 58, delimiting the bit lines in the stack of the above-mentioned layers. As an example, during this step, layer 51 and resistive heating element 49 are also etched.

FIG. 4 illustrates a structure obtained at the end of a step of deposition of layer 55 on the upper surface of the structure shown in FIG. 3. More particularly, FIG. 4 shows a perspective view of the structure.

During this step, layer 55 is for example deposited over the entire upper surface of the structure illustrated in FIG. 3, and more specifically on the upper surface of layer 57, on the upper surface of layer 37d, in trenches 58, and on the flanks of layers 57, 53, 47, and 51. As an example, layer 55 is deposited conformally, that is, with a constant thickness. As an example, layer 55 has a thickness in the range from 1 nm to 70 nm, for example in the range from 20 nm to 40 nm, for example in the order of 33 nm.

As an example, layer 55 is deposited by an atomic layer deposition (ALD) method.

At the end of this step, layer 55 is for example removed from the upper surface of layer 37d, at the bottom of trenches 58, to only be kept on the flanks of layers 57, 53, 47, and 51 and on the upper surface of layer 57.

FIGS. 5A and 5B illustrate a structure obtained at the end of a step of deposition of layer 59 on the upper surface of the structure shown in FIG. 4. More particularly, FIG. 5B corresponds to an enlargement of region B of FIG. 5A, FIG. 5A corresponding to a perspective view of the structure and FIG. 5B corresponding to a cross-section view of the structure.

During this step, layer 59 is deposited on top of trenches 58 by a non-conformal deposition method in such a way as to form a plug. The ambient air or gas (in the process chamber during this step) is then trapped in trenches 58, forming closed space 61.

The gas contained in closed space 61 is, for example, a neutral gas or air. As an example, the gas is nitrogen or argon. Closed space 61 has, for example, a height H in the range from 50 nm to 170 nm, for example in the order of 90 nm.

The bit lines are preferably all evenly spaced, trenches 58 thus all having a substantially identical width L.

As an example, the width L of trenches 58 is lower than 150 nm, for example lower than 118 nm, for example lower than 100 nm.

The deposition of layer 59 is for example performed by successive deposition of a plurality of sublayers, for example identical. As an example, the deposition of layer 59 is performed by successive deposition of three sublayers. As a variant, the deposition of layer 59 is performed by successive deposition of more than three sublayers.

The sublayers of layer 59 are for example deposited by a deposition method less conformal than ALD. As an example, the sublayers of layer 59 are not deposited by ALD. As an example, the sublayers of layer 59 are deposited by a method of chemical vapor deposition (CVD), for example a method of plasma enhanced chemical vapor deposition (PECVD). As a variant, layer 59 is deposited by a method of physical vapor deposition (PVD).

As an example, layer 59 penetrates into trench 58 down to a depth or distance D along the walls of the bit lines. Depth D is, for example, in the range from 10 nm to 100 nm, for example from 30 nm to 60 nm.

So that layer 59 can form a plug above and inside an upper portion of trench 58, layer 59 is deposited with a thickness E, from the upper surface of layer 55, greater than or equal to half width L. The thickness E of layer 59 is, for example, greater than or equal to 50 μm, for example greater than or equal to 59 nm, for example greater than or equal to 75 nm.

An advantage of the present embodiment is that the introduction of gas into a trench enables to decrease the relative permittivity of trenches separating two bit lines as compared with trenches filled with a dielectric material, for example silicon nitride.

Another advantage of the present embodiment is that it enables to limit the thermal conductivity between bit lines. This enables to limit the thermal disturbance of memory elements M, during the programming, with respect to neighboring elements.

Still another advantage of the present embodiment is that it enables to bring the bit lines closer together, and thus to decrease the size of memory circuits.

Many applications are likely to benefit from the advantages provided by electronic device 11, which electronic device 11 can thus be integrated into various types of devices.

As an example, electronic device 11 may be integrated into a device intended for the automotive industry. The electrification of motor vehicles causes a strong increase in the number of electronic components present in vehicles. The device for example comprises thyristors, rectifiers, transient voltage suppression diodes, modules, etc., intended to be incorporated into said vehicles. Further, driving assistance and driving automation have caused an increase in the number of electronic components in vehicles. The device for example comprises transient voltage suppression diodes, an electrostatic discharge protection, and common-mode filters enabling to protect the device against electrical hazards.

As an example, electronic device 11 may be integrated into a device intended for industry. In particular, the device is for example used for the development of green energies or for the electrification of infrastructures, for example for charging stations or for solar energy collection. The device may also be used in the field of the Internet of things or in the field of smart homes. The device is for example intended to be implemented in circuits for powering equipment, including for example 800-V or 1,200-V thyristors, ultrafast 1,200-V silicon carbide diodes, transient voltage suppression diodes, and electrostatic discharge protections. The device may also be used for the implementation of cloud computing systems, of 5G radio frequency communication networks, of data centers and of servers. The device for example comprises wide bandgap materials.

As an example, electronic device 11 may be integrated into a device intended to be used in personal electronics, for example to increase the volume of data exchanged by radio frequency communication, in 5G communication systems, or more generally in any connected device. The device is for example a cell phone, or smartphone, or forms part of an Internet of Things network. The device is for example connected by 5G, WiFi, or by broadband communication. The device for example comprises high-speed interfaces, for example with an advanced filtering and an electrostatic discharge protection.

As an example, electronic device 11 may be integrated into a device intended to be used in communications equipment, or in computers and peripherals. The device is for example used in 5G infrastructures and dedicated data centers. The device comprises, for example, silicon carbide diodes, Schottky power transistors, electrostatic discharge protections, and transient voltage suppression diodes. The device may also be used in satellites comprising, for example, integrated passive devices for radio frequency applications.

Various embodiments and variants have been described. Those skilled in the art will understand that certain features of these various embodiments and variants could be combined, and other variants will become apparent to those skilled in the art.

Further, although embodiments have been described in which memory elements M are covered with a layer 55, it may be provided to omit this layer, layer 59 is then deposited directly on the upper surface of layer 57 and extends along the lateral flanks of memory elements M. In order to preserve the chemical stability of layers 51, 47, 53, and 57, and in particular to protect them from oxidation, layer 59 extends in this variant all over the lateral flanks of memory elements M until it reaches the upper surface of layer 37d. In this variant, layer 59 has a thickness greater than or equal to 2 nm.

Finally, the practical implementation of the described embodiments and variants is within the abilities of those skilled in the art, based on the functional indications given above.

An electronic device (11) is summarized as including a memory circuit, the memory circuit including: a semiconductor substrate (13) inside and on top of which are arranged selection transistors; an interconnection stack (35), arranged on an upper surface of the semiconductor substrate; a plurality of memory elements (M) arranged above the interconnection stack and organized in an array, forming rows and columns, each memory element (M) including a stack of a resistive heating element (49), of a layer made of a phase-change material (47), and of a top electrode (53), the top electrode (53) being common to the memory elements of a same row so as to form bit lines (BL), wherein the memory elements (M) of two successive bit lines are separated by a trench (58) including, in a lower portion, a closed space (61) filled with a gas or with vacuum, the trench being closed by an insulating layer (59) extending over the upper surface of the memory elements (M) and in an upper portion of the trench (58).

The closed space (61) is filled with air.

The trench (58) has a width smaller than 105 nm, for example smaller than 118 nm, for example smaller than 100 nm.

The insulating layer (59) is made of silicon nitride.

The insulating layer (59) has a thickness, on the upper surface of the top electrode (53), greater than 75 nm.

The memory elements (M) of a same column are memory elements (M) of a same word line (WL), each selection transistor associated with the memory elements (M) of a same word line being coupled to a conductive via (63) running through the interconnection stack (35).

A method of manufacturing an electronic device (11) is summarized as including a memory circuit including a plurality of memory elements organized in an array, forming rows and columns, each memory element (M) including a stack of a resistive heating element (49), of a layer of phase-change material (47), and of a top electrode (53), the top electrode (53) being common to the memory elements of a same row so as to form bit lines (BL), wherein the memory elements (M) of two successive bit lines are separated by a trench, the method including the steps of: a) forming of selection transistors inside and on top of a semiconductor substrate (13); b) forming of an interconnection stack (35), arranged on an upper surface of the semiconductor substrate; c) forming of the memory elements (M) above the interconnection stack; and d) forming of an insulating layer (59) extending over the upper surface of the memory elements (M) and in an upper portion of the trenches (58) so as to close the trenches and create, in a lower portion of each trench, a closed space (61) filled with a gas.

The forming of the memory elements includes the steps of: forming of the resistive heating elements (49); deposition of the layer made of the phase-change material (47); deposition of the top electrode (53); and etching of the layer made of the phase-change material and of the top electrode (53).

The method includes, after step c), a step of deposition of another insulating layer (55) on the upper surface and the flanks of the memory elements (M).

The other insulating layer is formed by an atomic layer deposition method.

The insulating layer (59) is formed, at step d), by a method of plasma-enhanced chemical vapor deposition.

The insulating layer (59) is formed, at step d), by a physical vapor deposition method.

The method includes, after step b), a step of forming of a plurality of openings running through the entire height of the interconnection stack (35) and a step of filling of these openings with a metallic material so as to form conductive vias (63).

A method of use of an electronic device (11) includes the application of a current in the resistive heating element (49) of one of the memory elements (M), which results in a change in crystalline phase of the layer made of the phase-change material (47) of the memory element (M), allowing the storage of a data bit.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a memory circuit, the memory circuit including:
a semiconductor substrate;
a plurality of selection transistors inside and on the semiconductor substrate;
an interconnection stack on a first surface of the semiconductor substrate;
a plurality of memory elements on the interconnection stack and organized in an array, forming a plurality of rows and columns, each memory element including a stack, each stack including a resistive heating element, a layer made of a phase-change material, and a top electrode, the top electrode being common to the memory elements of a same row, forming a plurality of bit lines,
wherein the memory elements of two successive bit lines are separated by a trench including, in a first portion, a closed space filled with a gas, the trench being closed by an insulating layer extending over a first surface of the memory elements and in an second portion of the trench.

2. The electronic device according to claim 1, wherein the closed space is filled with air.

3. The device according to claim 1, wherein the trench has a width smaller than 105 nm.

4. The device according to claim 1, wherein the insulating layer is made of silicon nitride.

5. The device according to claim 1, wherein the insulating layer has a thickness, on the first surface of the top electrode, greater than 75 nm.

6. The device according to claim 1, wherein the memory elements of a same column are memory elements of a same word line, each selection transistor associated with the memory elements of a same word line being coupled to a conductive via extending through the interconnection stack.

7. The device according to claim 1, wherein each memory element of the plurality of memory elements is electrically coupled to a selection transistor of the plurality of selection transistors by a single conductive via extending across an entire thickness of the interconnection stack.

8. A method of manufacturing an electronic device, comprising:
forming, in a memory circuit including a plurality of memory elements organized in an array of rows and columns, a plurality of selection transistors inside and on top of a semiconductor substrate, each memory element including a stack of a resistive heating element, a layer of phase-change material, and a top electrode, the top electrode being common to the memory elements of a same row and forming bit lines, the memory elements of two successive bit lines being separated by a trench;
forming an interconnection stack on an upper surface of the semiconductor substrate;
forming the memory elements on the interconnection stack; and
forming a first insulating layer extending over the upper surface of the memory elements and in an upper portion of the trenches, the first insulating layer closing the trenches and creating, in a lower portion of each trench, a closed space filled with a gas.

9. The method according to claim 8, wherein the forming of the memory elements includes:
forming the resistive heating elements;
depositing the layer made of the phase-change material;
depositing the top electrode; and
etching the layer made of the phase-change material and the top electrode.

10. The method according to claim 8, comprising, after the forming the memory elements, depositing a second insulating layer on the upper surface and a plurality of sidewalls of the memory elements.

11. The method according to claim 10, wherein the second insulating layer is formed by an atomic layer deposition method.

12. The method according to claim 8, wherein the first insulating layer is formed, at step d), by a method of plasma-enhanced chemical vapor deposition.

13. The method according to claim 8, wherein the insulating layer is formed by a physical vapor deposition method.

14. The method according to claim 8, comprising, after the forming the interconnection stack, forming of a plurality of openings extending through the entire interconnection stack and forming a plurality of conductive vias by filling the plurality of openings with a metallic material.

15. A device, comprising:
a semiconductor substrate;
an interconnection stack on a first surface of the semiconductor substrate;
a plurality of memory elements on the interconnection stack, each memory element including a resistive heating element, a phase-change layer, and an electrode;
a plurality of trenches between adjacent memory elements, each trench including a closed space filled with a gas, each trench having an opening entirely covered by an insulating layer extending over a first surface of the memory elements.

16. The device according to claim 15, comprising a plurality of selection transistors inside and on the semiconductor substrate.

17. The device according to claim 16, wherein each selection transistor includes one N-type region and one P-type region.

18. The device according to claim 17, comprising a plurality of insulating trenches, each insulating trench extending into the semiconductor substrate from the first surface and separating a respective N-type region and P-type region of a respective selection transistor.

19. The device according to claim 15, wherein the interconnection stack includes a plurality of levels, each level including a first insulating layer of a first insulating material and a second insulating layer of a second insulating material different than the first insulating material.

20. The device according to claim 19, comprising a conductive via extending at least partially through the interconnection stack, the conductive via extending entirely through at least one level of the plurality of levels.

21. The device according to claim 15, wherein the resistive heating element is L-shaped, extending between the phase-change layer and a conductive track, the resistive heating element being surrounded by a thermal insulator layer.
